(19) United States
(12) Patent Application Publication
(10) Pub. No.: US 2016/0198583 A1
(43) Pub. Date: Jul. 7, 2016

(54) AC to DC Power Adapter with an AC Output

(71) Applicant: POLESTAR ELECTRIC INDUSTRIES CO., LTD., Jiangmen City (CN)

(72) Inventors: Cheng-Tao Chang, Hsinchu City (TW); Chu-Cheng Chang, Hsinchu City (TW); Cheng-Fen Chang, Hsinchu City (TW)

(21) Appl. No.: 14/941,783

(22) Filed: Nov. 16, 2015

(30) Foreign Application Priority Data
Jan. 7, 2015 (CN) 201520013452.3

(51) Int. Cl. H05K 7/02

(52) U.S. Cl. CPC H05K 7/02

(57) ABSTRACT

An AC to DC power adapter with an AC output has an AC output terminal serving to supply AC power to other equipment and connect to a peering AC to DC power adapter, such that multiple AC to DC power adapters can be connected in series with each other. Because all the AC to DC power adapters for installation at a site can be fully reused and no additional power adapters need to be purchased, material cost can be reduced. Also because the AC to DC power adapters can be relocated and reoriented and are sequentially connected with each other without having to concern locations of the fixed wall outlets to be connected, installation convenience can be ensured.

### BACKGROUND OF THE INVENTION

1. Field of the Invention

The present invention relates to a power adapter for decorative light and, more particularly, to an AC (Alternating Current) to DC (Direct Current) power adapter.

2. Description of the Related Art

It is well known that AC to DC power adapter can convert high-voltage AC power into safe and low-voltage DC power and has features of being compact in size and light in weight, making the AC to DC power adapter ideal for extensive applications, such as decorative string lights and household lights, in various occasions.

The conventional AC to DC power adapter is connected to an AC power source through an input terminal thereof. The input terminal is connected to an AC to DC conversion circuit board. An output terminal outputting safe and low-voltage DC power extends from the AC to DC conversion circuit board to supply the DC power to an electric appliance or a load connected to the AC to DC power adapter. Such conventional AC to DC power adapter can only be solely connected to the mains power. For example, supposing that there is only one AC outlet on a wall, after the conventional AC to DC power adapter of an electric appliance is plugged in the AC outlet, there is no AC outlet available for other electric appliances unless new AC outlets are further provided on the wall. However, additional labor and materials may arise from the newly installed AC outlets and become a barrier preventing from doing so.

### SUMMARY OF THE INVENTION

An objective of the present invention is to provide an AC to DC power adapter with an AC output ensuring installation convenience and material cost reduction.

To achieve the foregoing objective, the AC to DC power adapter with an AC output includes a housing, an AC input terminal, a DC output terminal, a conversion circuit board, and an AC output terminal.

The AC input terminal is mounted through the housing and is adapted to selectively connect to an AC power source.

The DC output terminal is mounted through the housing, has an outer end located outside the housing, and is adapted to connect to a decorative string light.

The conversion circuit board is mounted inside the housing and has an input terminal and an output terminal.

The input terminal is connected to the AC input terminal.

The output terminal is connected to the DC output terminal for the conversion circuit board to convert AC power inputted through the AC input terminal into DC power that is outputted to the DC output terminal.

The AC output terminal is mounted through the housing and has an inner end and an outer end.

The inner end is located inside the housing and is electrically connected to the AC input terminal.

The outer end is located outside the housing and selectively connects to the AC input terminal of a peering AC to DC power adapter.

Preferably, the AC output terminal is an AC power line that extends outwards to penetrate through the housing.

Preferably, the DC output terminal is a DC power line that extends outwards to penetrate through the housing, and the outer end of the DC output terminal adjoins the outer end of the AC output terminal.

Preferably, an output voltage of the AC output terminal is equal to an input voltage of the AC input terminal.

Preferably, an overload protection device is connected between the AC input terminal and the AC output terminal.

The benefits of the present invention reside in that when the AC to DC power adapter is in use, the AC input terminal is connected to a wall outlet in connection with a power grid and the DC output terminal is connected to a decorative string light, a lighting decoration or an electric appliance, such that the decorative string light, the lighting decoration or the electric appliance can be normally operated. Such wall outlet connected to a power grid usually has limited number of sockets allowing at most five to six AC to DC power adapters to be plugged therein. The power adapter in accordance with the present invention comes in handy, material cost can be reduced and installation convenience is ensured because all the AC to DC power adapters for installation at a site can be fully reused, no additional power adapters need to be purchased, and the AC to DC power adapters can be relocated and reoriented and are sequentially connected with each other.

Other objectives, advantages and novel features of the invention will become more apparent from the following detailed description when taken in conjunction with the accompanying drawings.

### BRIEF DESCRIPTION OF THE DRAWINGS

FIG. 1 is a schematic diagram of an AC to DC power adapter in accordance with the present invention; and

FIG. 2 is a circuit diagram of the AC to DC power adapter in FIG. 1.

### DETAILED DESCRIPTION OF THE INVENTION

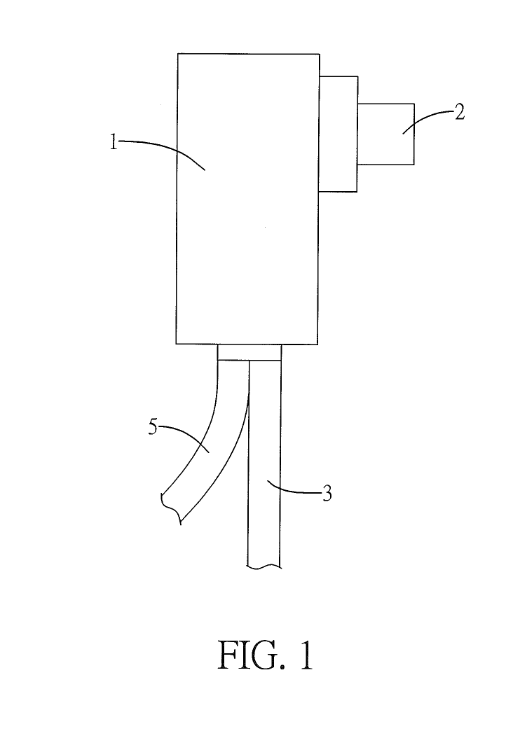

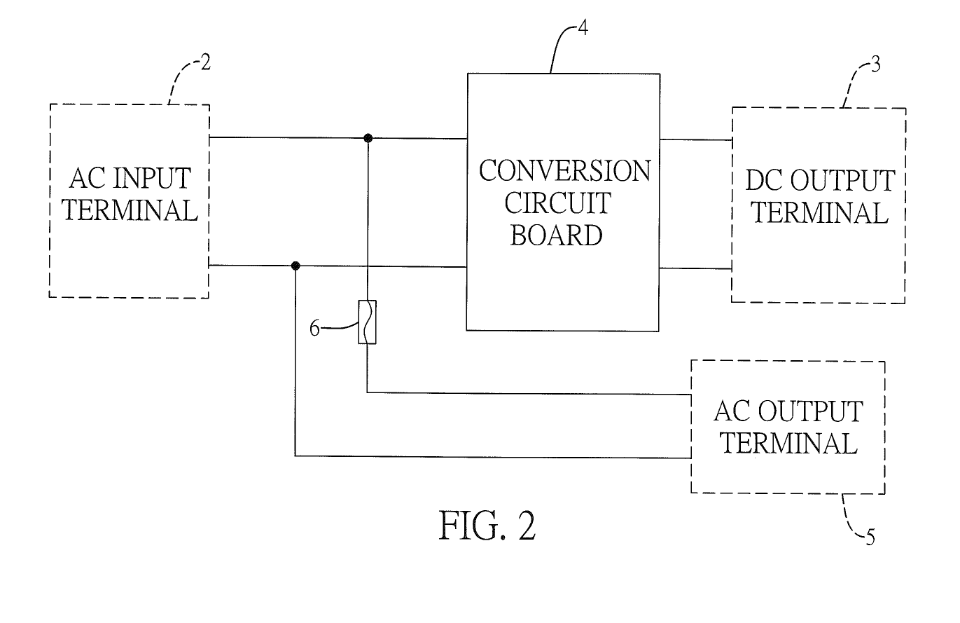

With reference to FIGS. 1 and 2, an AC to DC power adapter in accordance with the present invention includes a housing 1, an AC input terminal 2, a DC output terminal 3, a conversion circuit board 4, and an AC output terminal 5. The AC input terminal 2 and the DC output terminal 3 are mounted through the housing 1. The conversion circuit board 4 is mounted inside the housing 1 and has an input terminal and an output terminal. The input terminal is connected to the AC input terminal 2 and the output terminal is connected to the DC output terminal for the conversion circuit board 4 to convert AC power that is inputted through the AC input terminal 2 into DC power that is outputted through the DC output terminal 3. The AC output terminal 5 is mounted through the housing 1 and has an inner end and an outer end, in which the inner end is located inside the housing 1 and electrically connected to the AC input terminal 2. An output voltage of the AC output terminal 5 is equal to an input voltage of the AC input terminal 2.

The AC output terminal 5 is an AC power line that extends outwards to penetrate through the housing 1, and is not fixedly disposed, such that the AC output terminal 5 can be moved or reoriented according to site requirements. Accordingly, repeated wiring and installation work can be eliminated when the AC to DC power adapter is applied to different occasions, thereby saving labor hours and rendering operational convenience and flexibility upon installation at different application occasions.

The DC output terminal 3 has an inner end and an outer end, in which the DC output terminal 3 is a DC power line that extends outwards from the inner end inside the housing 1 to penetrate through the housing 1 and the outer end of the DC output terminal 3 is arranged to adjoin the AC output terminal 5 so as to provide an aesthetically pleasing appearance and facilitate wire routing and wire distribution.

To have circuit protection for an overload condition, an overload protection device 6 is connected between the AC input terminal 2 and the AC output terminal 5.

When the AC to DC power adapter is in use, the AC input terminal 2 is connected to a wall outlet in connection with a power grid and the DC output terminal 3 is connected to a decorative string light, a lighting decoration or an electric appliance, such that the decorative string light, the lighting decoration or the electric appliance can be normally operated. Such wall outlet connected to a power grid has usually two sockets allowing two conventional AC to DC power adapters to be plugged therein and at most for connection with five to six conventional AC to DC power adapters. The AC to DC power adapter in accordance with the present invention comes in handy when large amount of sockets are needed. Given an example of a garden with a length of 100 meters, supposing that multiple LED string lights are decorated on fifty trees located along the length of the garden, a power input terminal of an LED string light on the first tree is connected to the DC output terminal 3 of an instant AC to DC power adapter, the AC output terminal 5 of the instant AC to DC power adapter is connected to the AC input terminal 2 of the next AC to DC power adapter, and the power input terminal of another LED string light on the second tree is connected to the DC output terminal 3 of the next AC to DC power adapter. The installation of the LED string lights on the fifty trees can be done by repeatedly connecting each LED string light on a corresponding tree and a corresponding AC to DC power adapter and connecting two corresponding AC to DC power adapters adjacent to each other with the AC input terminal 2 of the AC to DC power adapter corresponding to the final tree connected to a socket of a wall inlet in connection to the power grid. Because all the AC to DC power adapters for installation at a site can be fully reused and no additional power adapters need to be purchased, material cost can be reduced. Also because the AC to DC power adapters can be relocated and reoriented and are sequentially connected with each other without having to concern locations of the fixed wall outlets to be connected, installation convenience can be ensured.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. An AC (Alternating Current) to DC (Direct Current) power adapter with an AC output, comprising:
a housing;
an AC input terminal mounted through the housing and adapted to selectively connect to an AC power source;
a DC output terminal mounted through the housing, having an outer end located outside the housing, and adapted to connect to a decorative string light;
a conversion circuit board mounted inside the housing and having:
an input terminal connected to the AC input terminal; and
an output terminal connected to the DC output terminal for the conversion circuit board to convert AC power inputted through the AC input terminal into DC power that is outputted to the DC output terminal; and
an AC output terminal mounted through the housing and having:
an inner end located inside the housing and electrically connected to the AC input terminal; and
an outer end located outside the housing and selectively connected to the AC input terminal of a peering AC to DC power adapter.

2. The AC to DC power adapter as claimed in claim 1, wherein the AC output terminal is an AC power line that extends outwards to penetrate through the housing.

3. The AC to DC power adapter as claimed in claim 2, wherein the DC output terminal is a DC power line that extends outwards to penetrate through the housing, and the outer end of the DC output terminal adjoins the outer end of the AC output terminal.

4. The AC to DC power adapter as claimed in claim 1, wherein an output voltage of the AC output terminal is equal to an input voltage of the AC input terminal.

5. The AC to DC power adapter as claimed in claim 1, wherein an overload protection device is connected between the AC input terminal and the AC output terminal.
